(19) United States
(12) Patent Application Publication
(10) Pub. No.: US 2026/0143631 A1
(43) Pub. Date: May 21, 2026

(54) LIQUID COOLING ASSEMBLY

(71) Applicants: INVENTEC (PUDONG) TECHNOLOGY CORPORATION, Shanghai (CN); INVENTEC CORPORATION, Taipei City (TW)

(72) Inventors: Kai-Yang TUNG, Taipei City (TW); Hung-Ju CHEN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/208,684

(22) Filed: May 15, 2025

(30) Foreign Application Priority Data
Nov. 15, 2024 (CN) 202411644300.3

(51) Int. Cl. H05K 7/20

(52) U.S. Cl. CPC H05K 7/20272; H05K 7/20254

(57) ABSTRACT

A liquid cooling assembly includes a liquid delivery component and a liquid absorbing component. The liquid delivery component includes a housing, an inlet joint and at least one outlet joint, and the inlet joint and the outlet joint are disposed on the housing. The liquid absorbing component is disposed on the housing and corresponds to the inlet joint and the outlet joint.

### CROSS-REFERENCE TO RELATED APPLICATIONS

This non-provisional application claims priority under 35 U.S.C. § 119(a) on Patent Application No(s). 202411644300.3 filed in China, on Nov. 15, 2024, the entire contents of which are hereby incorporated by reference.

### BACKGROUND OF THE INVENTION

### Technical Field of the Invention

The invention relates to a liquid cooling assembly.

### Description of the Related Art

Generally, working fluid in cold plates is often a liquid. In order to reduce the risk of leakage from joints of the cold plate, a recess is typically added beneath the joints to temporarily store the leaked liquid, thus reducing the possibility of liquid contacting the electronic components around the cold plate. However, the amount of liquid that the recess can store is limited, as the depth of the recess must be less than the heights of the joints to avoid interfering with the assembly of the pipes at the joints. Even though the recess can prevent the leaked liquid from directly flowing onto the surfaces of the electronic components, when the server equipped with this cold plate is vibrated or moved, or the cold plate is blown by a fan, the liquid in the recess may overflow due to the movement of the liquid surface, potentially damaging the electronic components.

On the other hand, besides the risk of leakage in the cold plate, other components through which the working fluid flows also have the potential for leakage. For example, the joints of a manifold are also prone to leakage. However, unlike cold plates, no groove can be set beneath the joints of the manifold to temporarily store the leaked liquid, so the leaked liquid may directly contact the electronic components around the manifold, causing potential damage to the electronic components.

### SUMMARY OF THE INVENTION

The invention provides a liquid cooling assembly that can reduce the risk of leaked liquid damaging the surrounding electronic components.

One embodiment of the invention provides a liquid cooling assembly. The liquid cooling assembly includes a liquid delivery component and a liquid absorbing component. The liquid delivery component includes a housing, an inlet joint and at least one outlet joint, and the inlet joint and the outlet joint are disposed on the housing. The liquid absorbing component is disposed on the housing and corresponds to the inlet joint and the outlet joint.

According to the liquid cooling assembly as discussed in the above embodiments, the liquid absorbing component is disposed on the housing of the liquid delivery component and corresponds to the inlet joint and the outlet joint. By this configuration, the liquid absorbing component can absorb the liquid leaked from the inlet joint and the outlet joint of the liquid delivery component, which helps prevent the leaked liquid from directly contacting the electronic components around the liquid delivery component, thereby reducing the risk of damage to the electronic components.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a liquid cooling assembly according to a first embodiment of the invention;

FIG. 2 is a cross-sectional view of the liquid cooling assembly in FIG. 1;

FIG. 3 is a cross-sectional view of the liquid cooling assembly in FIG. 2 when leakage occurs;

FIG. 4 is a perspective view of a liquid cooling assembly according to a second embodiment of the invention; and

FIG. 5 is another perspective view of the liquid cooling assembly in FIG. 4.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

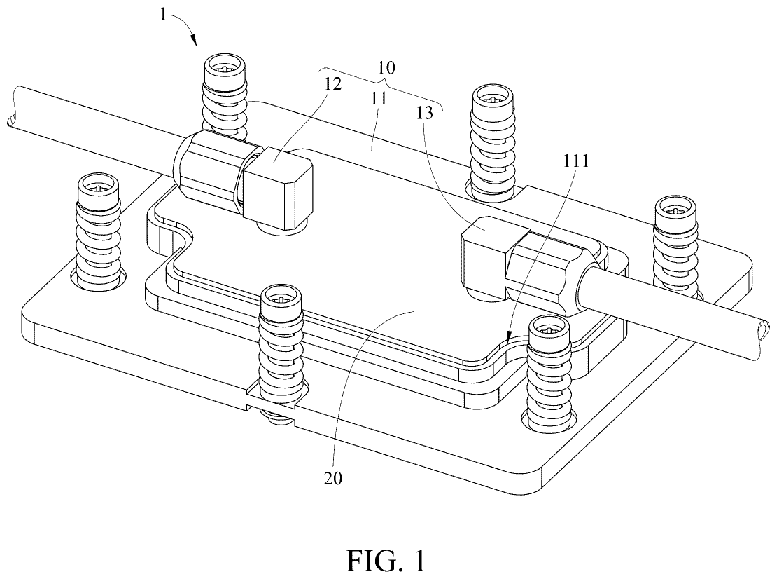

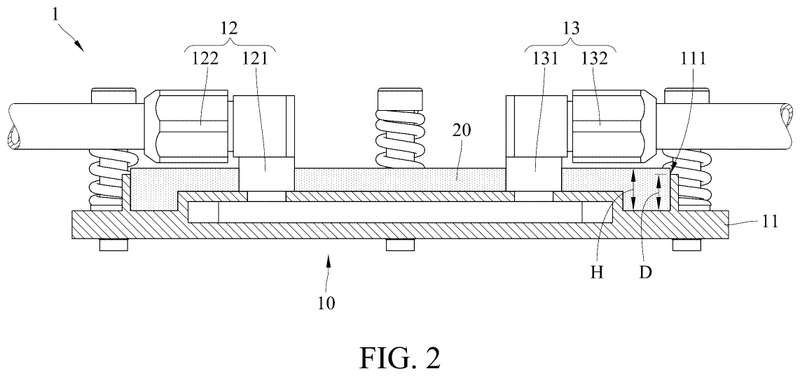

Referring to FIGS. 1 and 2, FIG. 1 is a perspective view of a liquid cooling assembly according to a first embodiment of the invention, and FIG. 2 is a cross-sectional view of the liquid cooling assembly in FIG. 1. In this embodiment, the liquid cooling assembly 1 includes a liquid delivery component 10 and a liquid absorbing component 20. The liquid cooling assembly 1 is, for example, suitable for use in a server.

The liquid delivery component 10 is, for example but not limited to, a cold plate. The liquid delivery component 10 includes a housing 11, an inlet joint 12, and an outlet joint 13. The housing 11 includes a liquid collecting recess 111. The inlet joint 12 includes a housing assembling portion 121 and a pipe assembling portion 122 connected to each other, and the housing assembling portion 121 and the pipe assembling portion 122 of the inlet joint 12 are, for example but not limited to, perpendicular to each other. The outlet joint 13 includes a housing assembling portion 131 and a pipe assembling portion 132 connected to each other, and the housing assembling portion 131 and the pipe assembling portion 132 of the outlet joint 13 are, for example but not limited to, perpendicular to each other. The housing assembling portion 121 of the inlet joint 12 and the housing assembling portion 131 of the outlet joint 13 are partially located in the liquid collecting recess 111 and are connected to the housing 11. The pipe assembling portion 122 of the inlet joint 12 and the pipe assembling portion 132 of the outlet joint 13 are located outside the liquid collecting recess 111.

The liquid absorbing component 20 is, for example, made of a liquid-absorbent and expandable material. For example, the liquid absorbing component 20 may be a polyethylene glycol foam, but the invention is not limited thereto. The liquid absorbing component 20 is disposed in the liquid collecting recess 111 of the housing 11, and a height H of the liquid absorbing component 20 is, for example but not limited to, greater than a depth D of the liquid collecting recess 111 for increasing a liquid absorption capacity. The liquid absorbing component 20 is separated from the pipe assembling portion 122 of the inlet joint 12 and the pipe assembling portion 132 of the outlet joint 13.

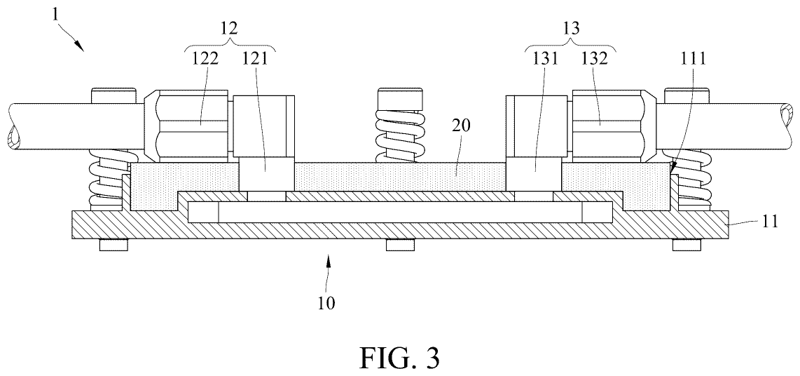

Then, referring to FIG. 3, FIG. 3 is a cross-sectional view of the liquid cooling assembly in FIG. 2 when leakage occurs.

When leakage occurs at the inlet joint 12 or the outlet joint 13 of the liquid delivery component 10, the leaked liquid is absorbed by the liquid absorbing component 20 to prevent the leaked liquid from directly contacting the electronic components around the liquid delivery component 10, thereby reducing the risk of damage to the electronic components.

In this embodiment, by the configuration of the cold plate with the liquid absorbing component 20 in the liquid collecting recess 111, the liquid storage amount can be increased by 10% to 20% compared to the configuration of a cold plate without the liquid absorbing component 20 in the liquid collecting recess 111. Furthermore, by having the liquid absorbing component 20 to absorb and store the leaked liquid, the time for personnel to perform maintenance can be delayed.

After the liquid absorbing component 20 absorbs liquid, it expands and presses against the pipe assembling portion 122 of the inlet joint 12 and the pipe assembling portion 132 of the outlet joint 13. For example, the height of the liquid absorbing component 20 after absorbing the liquid may increase from about 1 cm to about 1.5 cm. Additionally, the configuration where the liquid absorbing component 20 presses against the pipe assembling portion 122 of the inlet joint 12 and the pipe assembling portion 132 of the outlet joint 13 allows the liquid absorbing component 20 to quickly absorb the liquid leaked from the inlet joint 12 or the outlet joint 13.

It should be noted that the liquid absorbing component 20 is not limited to pressing against the pipe assembling portion 122 of the inlet joint 12 and the pipe assembling portion 132 of the outlet joint 13 after absorbing liquid. In other embodiments, the liquid absorbing component may press against the pipe assembling portion 122 of the inlet joint 12 and the pipe assembling portion 132 of the outlet joint 13 before absorbing liquid. Alternatively, in one embodiment, the liquid absorbing component may not press against the pipe assembling portion of the inlet joint and the pipe assembling portion of the outlet joint, regardless of whether liquid has been absorbed.

Additionally, the liquid absorbing component 20 is not limited to being made of an expandable material. In other embodiments, the liquid absorbing component 20 may be made of a non-expandable material.

In one embodiment, the liquid absorbing component may be disposed in the liquid collecting recess by a partial removal manner, in order to prevent interference between the liquid absorbing component and the inlet joint and outlet joint.

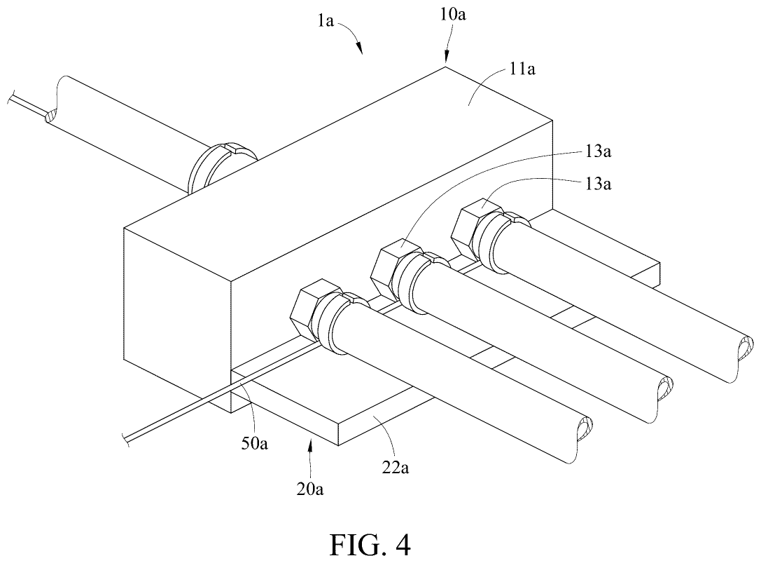

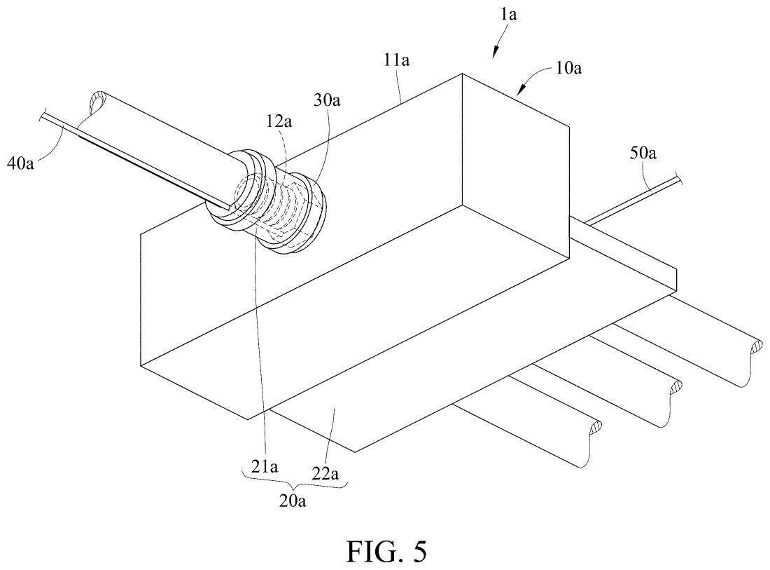

Then, referring to FIGS. 4 and 5, FIG. 4 is a perspective view of a liquid cooling assembly according to a second embodiment of the invention, and FIG. 5 is another perspective view of the liquid cooling assembly in FIG. 4. In this embodiment, the liquid cooling assembly 1a includes a liquid delivery component 10a and a liquid absorbing component 20a.

The liquid delivery component 10a is, for example but not limited to, a manifold. The liquid delivery component 10a includes a housing 11a, an inlet joint 12a and a plurality of outlet joints 13a. The inlet joint 12a and the outlet joints 13a are dispose on two opposite sides of the housing 11a.

The liquid absorbing component 20a includes a first absorbing portion 21a and a second absorbing portion 22a. For example, the first absorbing portion 21a and the second absorbing portion 22a may be made of a liquid-absorbent and expandable material. For instance, the first absorbing portion 21a and the second absorbing portion 22a may be polyethylene foams.

The first absorbing portion 21a is disposed on the housing 11a and corresponds to the inlet joint 12a. For example, the first absorbing portion 21a is wrapped around a connection between the inlet joint 12a and the housing 11a. Additionally, the liquid cooling assembly 1a may also include a fastener 30a, such as a buckle, which is used to secure the first absorbing portion 21a at the connection between the inlet joint 12a and the housing 11a. The second absorbing portion 22a is disposed on the housing 11a and corresponds to the outlet joints 13a. For example, the second absorbing portion 22a is fixed to the housing 11a by adhesive, and is located below the outlet joints 13a.

In this embodiment, the liquid cooling assembly 1a may also include a first leakage detector 40a and a second leakage detector 50a. The first leakage detector 40a and the second leakage detector 50a may, for example, be leakage detection cables. The first leakage detector 40a is partially located between the first absorbing portion 21a and the inlet joint 12a, while the second leakage detector 50a is partially located on the second absorbing portion 22a.

When leakage occurs at the inlet joint 12a and the outlet joint 13a, the first absorbing portion 21a and the second absorbing portion 22a absorb the leaked liquid to prevent the leaked liquid from directly contacting the electronic components around the liquid delivery component 10a, thereby reducing the risk of damage to the electronic components.

In addition, by having the first leakage detector 40a partially between the first absorbing portion 21a and the inlet joint 12a, and the second leakage detector 50a partially on the second absorbing portion 22a, leakage at the inlet joint 12a and the outlet joints 13a can be detected. This configuration allows the leakage detectors to send a leakage signal when leakage occurs, notifying maintenance personnel.

It should be noted that the first leakage detector 40a and the second leakage detector 50a are optional components, and may be omitted in other embodiments.

It should be noted that the first absorbing portion 21a is not limited to being wrapped around the connection between the inlet joint 12a and housing 11a. In other embodiments, the first absorbing portion may be disposed below the inlet joint, similar to the second absorbing portion.

Additionally, the second absorbing portion 22a is not limited to being located below the outlet joints 13a. In other embodiments, the number of second absorbing portions may be multiple, and the second absorbing portions may be respectively wrapped around the outlet joints, similar to the first absorbing portion.

In one embodiment of the invention, the server of the invention can be used for artificial intelligence (AI) computing, edge computing, as well as 5G server, cloud server, or vehicle-to-everything (V2X) server.

According to the liquid cooling assemblies as discussed in the above embodiments, the liquid absorbing component is disposed on the housing of the liquid delivery component and corresponds to the inlet joint and the outlet joint. By this configuration, the liquid absorbing component can absorb the liquid leaked from the inlet joint and the outlet joint of the liquid delivery component, which helps prevent the leaked liquid from directly contacting the electronic components around the liquid delivery component, thereby reducing the risk of damage to the electronic components.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A liquid cooling assembly, comprising:
a liquid delivery component, comprising a housing, an inlet joint and at least one outlet joint, wherein the inlet joint and the at least one outlet joint are disposed on the housing; and
a liquid absorbing component, disposed on the housing and corresponding to the inlet joint and the at least one outlet joint.

2. The liquid cooling assembly according to claim 1, wherein the liquid delivery component is a cold plate, the housing comprises a liquid collecting recess, the inlet joint and the at least one outlet joint are at least partially located in the liquid collecting recess, and the liquid absorbing component is disposed in the liquid collecting recess of the housing.

3. The liquid cooling assembly according to claim 2, wherein a height of the liquid absorbing component is greater than a depth of the liquid collecting recess.

4. The liquid cooling assembly according to claim 2, wherein each of the inlet joint and the at least one outlet joint comprises a housing assembling portion and a pipe assembling portion connected to each other, the housing assembling portion of the inlet joint and the housing assembling portion of the at least one outlet joint are partially located in the liquid collecting recess, the pipe assembling portion of the inlet joint and the pipe assembling portion of the at least one outlet joint are located outside the liquid collecting recess, the liquid absorbing component is separated from the pipe assembling portion of the inlet joint and the pipe assembling portion of the at least one outlet joint.

5. The liquid cooling assembly according to claim 4, wherein the housing assembling portion and the pipe assembling portion of the inlet joint are perpendicular to each other, and the housing assembling portion and the pipe assembling portion of the at least one outlet joint are perpendicular to each other.

6. The liquid cooling assembly according to claim 4, wherein the liquid absorbing component is made of a liquid-absorbent and expandable material; after the liquid absorbing component absorbs liquid, the liquid absorbing component expands and presses against the pipe assembling portion of the inlet joint and the pipe assembling portion of the at least one outlet joint.

7. The liquid cooling assembly according to claim 1, wherein the liquid delivery component is a manifold, the at least one outlet joint comprises a plurality of outlet joints, the liquid absorbing component comprises a first absorbing portion and a second absorbing portion, the first absorbing portion is disposed on the housing and corresponds to the inlet joint, and the second absorbing portion is disposed on the housing and corresponds to the plurality of outlet joints.

8. The liquid cooling assembly according to claim 7, wherein the first absorbing portion is wrapped around a connection between the inlet joint and the housing, and the second absorbing portion is located below the plurality of outlet joints.

9. The liquid cooling assembly according to claim 8, further comprising a first leakage detector and a second leakage detector, wherein the first leakage detector is partially located between the first absorbing portion and the inlet joint, and the second leakage detector is partially located on the second absorbing portion.

10. The liquid cooling assembly according to claim 1, wherein the liquid absorbing component is a polyvinyl alcohol foam.
